(19) United States
(12) Patent Application Publication
(10) Pub. No.: US 2011/0063250 A1
(43) Pub. Date: Mar. 17, 2011

(54) Organic conductive composition and touch panel input device including the same

(75) Inventors: Jong Young Lee, Suwon (KR); Yongsoo Oh, Seongnam (KR); Ho Joon Park, Seoul (KR)

(73) Assignee: SAMSUNG ELECTRO-MECHANICS CO., LTD., Suwon (KR)

(21) Appl. No.: 12/923,086

(22) Filed: Aug. 31, 2010

Related U.S. Application Data
(63) Continuation-in-part of application No. 12/654,428, filed on Dec. 18, 2009.

(30) Foreign Application Priority Data
Aug. 31, 2009 (KR) 10-2009-0081505
Aug. 25, 2010 (KR) 10-2010-0082675

(51) Int. Cl. G06F 3/045; H01L 51/30; H01B 1/12

(52) U.S. Cl. 345/174; 438/50; 252/500

(57) ABSTRACT

An organic conductive composition and a touch panel input device are provided. The organic conductive composition includes: 10 to 70 parts by weight of a conductive polymer; 0.01 to 40 parts by weight of a dopant selected from the group consisting of Lewis acids capable of accepting electrons; 1 to 40 parts by weight of a binder; and 1 to 30 parts by weight of a viscosity control agent, wherein the organic conductive composition has a viscosity ranging from 1 to 100,000 mPas.

### CROSS-REFERENCE TO RELATED APPLICATIONS

This application is a continuation-in-part of U.S. patent application Ser. No. 12/654,428, filed on Dec. 18, 2009, now pending, which further is based on and claims the benefit of priority from the prior Korean Patent Application Nos. 10-2009-0081505 filed on Aug. 31, 2009 and 10-2010-0082675 filed on Aug. 25, 2010, in the Korean Intellectual Property Office, the disclosures of which are incorporated herein by reference.

### BACKGROUND OF THE INVENTION

1. Field of the Invention

The present invention relates to an organic conductive composition and a touch panel input device including the same, and more particularly, to an organic conductive composition which has excellent transparency and low surface resistance and is applicable to various printing methods, and a touch panel input device including the same.

2. Description of the Related Art

Recently, as computers, various household appliances, and communications devices have been digitalized and their performances have rapidly improved, the implementation of portable displays having large screens is increasingly demanded. In order to implement portable and flexible displays with large screens, a flexible display material is required which can be folded or rolled like a sheet of paper.

Therefore, electrode materials for display panels should be transparent and have low resistance. Furthermore, the electrode materials should have high flexibility such that they are mechanically stable even when a device is bent or folded. Moreover, the electrode materials should have a thermal expansion coefficient similar to that of a plastic substrate such that a short circuit does not occur and a change in surface resistance is not large even when the device is overheated.

Flexible electrode materials make it possible to manufacture a display in an arbitrary form. Therefore, such a display can be used in a portable display device, as a clothing trademark, a billboard, a product display stand price display tag, a large-sized electric illumination system, and the like, which can change colors or patterns. Hence, the utilization rate of the flexible display is high.

Currently, a chemical deposition method, a magneton sputtering method, and a reactive evaporation deposition method are being actively developed both domestically and internationally as methods of fabricating a transparent electrode. In the chemical deposition method, oxides and compounds of various metals such as indium, tin, zinc, titanium, and cesium are used. However, since a state of vacuum is required to coat a substrate with a metallic oxide, the manufacturing cost inevitably increases.

Recently, a method using a conductive polymer has been proposed as a method by which a transparent electrode can be manufactured at a low cost. When an electrode is manufactured using a conductive polymer, a variety of existing polymer coating methods may be used. Therefore, it is possible to reduce the manufacturing cost and the required number of operations. That is, a transparent electrode formed of a conductive polymer such as polyacetylene, polypyrrole, polyaniline, or polythiopene has more advantages in a manufacturing process than a transparent indium tin oxide (ITO) electrode, when the transparent electrode is applied to the process of manufacturing a flexible display or electronic illumination system. Furthermore, since the transparent electrode is more flexible and does not break easily, it may extend the lifespan of a device such as a touch screen which requires a very flexible electrode. Despite such advantages, however, the conductive polymer absorbs visible rays, and a conductivity characteristic of an organic electrode formed of the conductive polymer increases in proportion to the thickness of the electrode. Therefore, when a conductive film is applied to a small thickness to increase transmittance, surface resistance increases. In this case, it may be difficult to apply the organic electrode to the application fields of the transparent electrode such as touch panel and flexible display. In particular, when a transparent electrode is manufactured using Baytron P, which is water-dispersed polythiopene obtained by separating a conductive polymer into nanoparticles, in order to improve the processability of the conductive polymer; it exhibits a surface resistance of 1 MΩ/sq at a transmittance of 85%. Consequently, it may be difficult to use the electrode as a transparent electrode for a display.

Therefore, there is a need for the development of a transparent electrode material having excellent transparency and low surface resistance.

### SUMMARY OF THE INVENTION

An aspect of the present invention provides an organic conductive composition which has excellent transparency and low surface resistance and is applicable to various printing methods, and a touch panel input device including the same.

According to an aspect of the present invention, there is provided an organic conductive composition including: 10 to 70 parts by weight of a conductive polymer; 0.01 to 40 parts by weight of a dopant selected from the group consisting of Lewis acids capable of accepting electrons; 1 to 40 parts by weight of a binder; and 1 to 30 parts by weight of a viscosity control agent, wherein the organic conductive composition has a viscosity ranging from 1 to 100,000 mPas.

The viscosity control agent may include one or more material selected from the group consisting of diaminodiphenylmethane (DMA), 4,4′-oxydianiline (ODA), diethylene triamine (DETA), triethylene tetramine (TETA), ethylene diamine (EDA), and hexamethylenediamine (HMDA).

The organic conductive composition may have a viscosity ranging from 60 to 200 mPas and may be applied to gravure printing.

The organic conductive composition may have a viscosity ranging from 300 to 70,000 mPas and may be applied to screen printing.

The organic conductive composition may have a viscosity ranging from 1 to 50 mPas and may be applied to inkjet printing.

The organic conductive composition may have a viscosity ranging from 10,000 to 100,000 mPas and may be applied to offset printing.

The conductive polymer may include one or more material selected from the group consisting of polythiopene, polyaniline, polyacetylene, polypyrrole, polyphenylenevinylene.

The dopant may include one or more material selected from the group consisting of sulfonate compound, a boron compound, and a phosphate compound.

According to another aspect of the present invention, there is provided a touch panel input device, including: a first substrate; and a first organic conductive composition including: 10 to 70 parts by weight of a conductive polymer; 0.01 to 40 parts by weight of a dopant selected from the group consisting of Lewis acids capable of accepting electrons; 1 to 40 parts by weight of a binder; and 1 to 30 parts by weight of a viscosity control agent, wherein the organic conductive composition has a viscosity ranging from 1 to 100,000 mPas.

The first substrate may be formed of polyethylene terephthalate (PET), polycarbonate (PC), polymethyl methacrylate (PMMA), polyethylenenaphthalate (PEN), polyethersulfone (PES), or cyclo-olefin copolymer (COC).

The touch panel input device may further include: a second substrate disposed opposite to the first substrate; and

a second organic conductive film formed on the second substrate, wherein the first organic conductive film is deformed by a touch to partially come in contact with the second organic conductive film.

The touch panel input device may further include: a second substrate disposed opposite to the first substrate; and a second organic conductive film formed on the second substrate, wherein the first and second organic conductive films detect a change in electrostatic capacity caused by a touch of the first substrate.

According to another aspect of the present invention, there is provided a method of manufacturing a touch panel input device, including: preparing an organic conductive composition, the organic conductive composition including: 10 to 70 parts by weight of a conductive polymer; 0.01 to 40 parts by weight of a dopant selected from the group consisting of Lewis acids capable of accepting electrons; 1 to 40 parts by weight of a binder; and 1 to 30 parts by weight of a viscosity control agent, wherein the organic conductive composition has a viscosity ranging from 1 to 100,000 mPas; and forming a first organic conductive film on the first substrate using the organic conductive composition.

The first organic conductive film may be formed by inkjet printing, screen printing, gravure printing or offset printing.

The method may further include performing a surface treatment on a surface of the first substrate where the first organic conductive film is to be formed, in order to increase the surface tension of the first substrate, before forming the first organic conductive film on the first substrate.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a diagram illustrating a doping mechanism of poly3,4-ethylenedioxythiophene (PEDOT) and polystyrene sulfonate;

FIG. 2 is a schematic cross-sectional view of a touch panel input device according to an embodiment of the present invention;

FIG. 3 is a schematic cross-sectional view of a touch panel input device according to another embodiment of the present invention;

FIG. 4 is a graph showing a rate of viscosity of an organic conductive composition according to an embodiment of the present invention; and

FIG. 5 is a graph showing a rate of resistivity of an organic conductive composition according to an embodiment of the present invention.

### DETAILED DESCRIPTION OF THE PREFERRED EMBODIMENT

The present invention relates to an organic conductive composition including a conductive polymer, a dopant, and a viscosity control agent. The organic conductive composition according to an embodiment of the present invention has a viscosity ranging from 1 to 100,000 mPas and its viscosity can be easily controlled according to a printing method. The organic conductive composition according to an embodiment of the present invention not only has excellent transparency, but also low surface resistance. Accordingly, the organic conductive composition may be suitable for use in a touch panel input device. Further, the organic conductive composition according to the embodiment of the present invention is composed of a similar material to a substrate of the input device and has a small difference in thermal expansion coefficient from the substrate. Therefore, the organic conductive composition may increase the durability of the input device.

Hereinafter, the respective components of the organic conductive composition will be described in detail.

The conductive polymer included in the organic conductive composition according to the embodiment of the present invention is not specifically limited. For example, polythiopene, polyaniline, polyacetylene, polypyrrole, polyphenylenevinylene, and derivatives thereof may be used as the conductive polymer, either in an independent or combined manner.

More specifically, poly3,4-ethylenedioxythiophene (hereinafter, referred to as PEDOT) expressed by following Chemical Formula 1 may be used as the polythiopene.

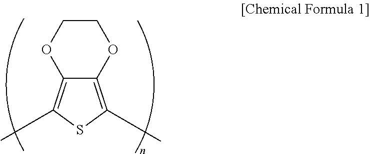

The polythiopene has high electrical conductivity and environmental affinity. The polythiopene has a disadvantage in that it is not easily dissolved. However, when the polythiopene is used with a dopant, the solubility thereof may increase.

The content of the conductive polymer may range from 0.01 to 70 parts by weight with respect to the entire composition. When the content is less than 0.01 parts by weight, the electrical conductivity of the organic conductive composition may decrease. Furthermore, when the content exceeds 70 parts by weight, the solubility or transparency thereof may decrease.

A Lewis acid capable of accepting electrons may be used as the dopant which is included in the organic conductive composition to lower electrical resistance. In the organic conductive composition according to the embodiment of the present invention, the dopant serves to increase the solubility of the conductive polymer and lower electrical resistance to improve the electrical conductivity of the organic conductive composition.

The dopant is not specifically limited. A sulfonate compound, a boron compound, a phosphate compound, a conductive carbon black and so on may be taken as examples of the dopant. They may be used in an independent or combined manner.

Polystyrene sulfonate, benzene sulfonate, alkylnaphthalene sulfonate, methane sulfonate, camphor sulfonate, naphthalene sulfonate, or para-toluene sulphonate may be taken as an example of the sulfonate compound. Tetrafluoroboron may be taken as an example of the boron compound. Hexafluoro phosphate or poly alkylenedioxythiophene may be taken as an example of the phosphate compound.

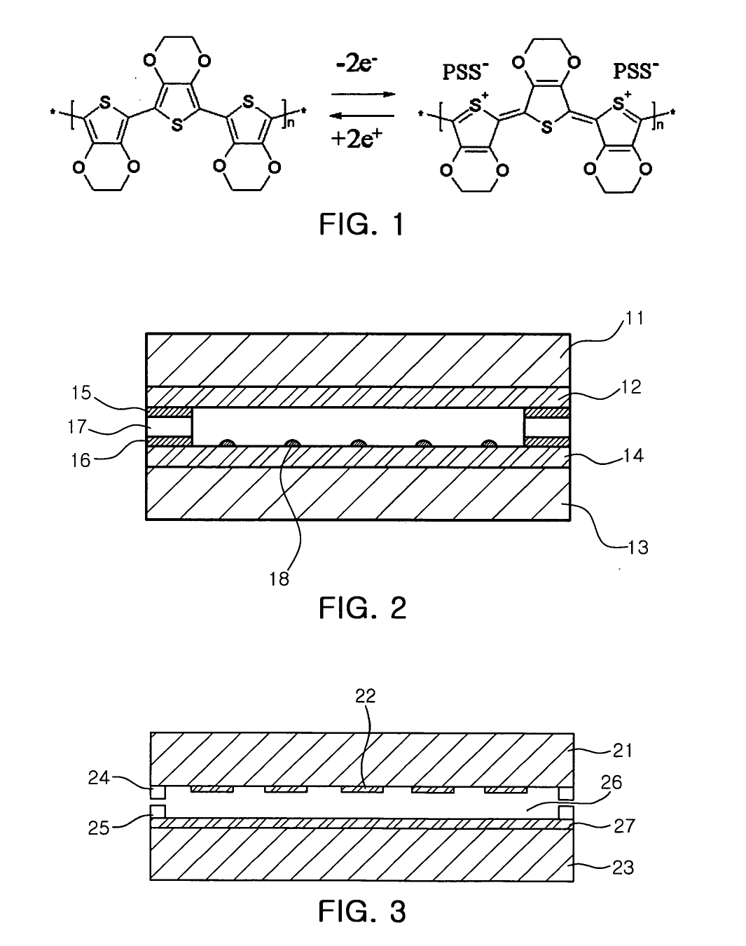

When the PEDOT is used as the conductive polymer and the polystyrene sulfonate is used as the dopant, the solubility of the PEDOT increases, which makes it easy to process the PEDOT in a desired form. FIG. 1 is a diagram illustrating a doping mechanism of the PEDOT and the polystyrene sulfonate. Referring to FIG. 1, S atoms of thiophene in the PEDOT lose an electron to exhibit a positive charge, and the polystyrene sulfonates lose H⁺ to exhibit a negative charge. At this time, the conjugation between double bonds existing in the PEDOT causes an electric current to flow.

The content of the dopant may range from 0.01 to 40 parts by weight with respect to the entire composition. When the content is less than 0.01 parts by weight, the solubility of the conductive polymer may decrease, and the electrical resistance may increase. On the other hand, when the content exceeds 40 parts by weight, the transparency may decrease.

The binder included in the organic conductive composition according to the embodiment of the present invention serves to improve the viscosity of the organic conductive composition. Alkyl glycidyl ether (meta) acrylate with a carbon number of 2 to 8, phenyl glycidyl ether (meta) acrylate, (meta) acrylate, multi-functional (meta) acrylate, ultraviolet (UV) or thermally curable epoxy, urethanes, or an acrylic-urethane copolymer may be taken as an example of the binder. They may be used in an independent or combined manner.

The binder may be used as a low-molecular-weight binder having a weight average molecular weight (Mw) of hundred thousand or less or a high-molecular-weight binder having a weight average molecular weight (Mw) of hundred thousand or more.

The content of the binder may range from 1 to 40 parts by weight with respect to the entire composition. When the content is less than 1 part by weight, an adhesive force with a substrate may decrease. When the content exceeds 40 parts by weight, the electrical conductivity may decrease.

The viscosity control agent usable herein may be an amine-based viscosity control agent. The amine-based viscosity control agent is not specifically limited. For example, the amine-based viscosity control agent include a crosslink type amine-based viscosity control agent, such as diaminodiphenylmethane (DMA) and 4,4′-oxydianiline (ODA), or a linear type amine-based viscosity control agent, such as diethylene triamine (DETA), triethylene tetramine (TETA), ethylene diamine (EDA), and hexamethylenediamine (HMDA).

The content of the viscosity control agent may range from 1 to 30 parts by weight with respect to the entire composition. When the content exceeds 30 parts by weight, the electric conductivity may decrease.

The organic conductive composition according to the embodiment of the present invention includes the viscosity control agent and has a viscosity ranging from 1 to 100,000 mPas. The viscosity may be appropriately controlled depending on a printing method which is applied to a process of forming an organic conductive film.

When the organic conductive film is formed by inkjet printing, the viscosity of the organic conductive composition may range from 1 to 50 mPas. When the conductive film is formed by screen printing, the viscosity of the organic conductive composition may range from 300 to 70,000 mPas.

The inkjet printing or screen printing is suitable for patterning and forming an organic conductive film.

Also, when the organic conductive film is formed by gravure printing, the viscosity of the organic conductive composition may be 400 mPas or less, specifically 60 to 200 mPas. The gravure printing may be applied to pattern printing as well as the entire printing.

When the conductive film is formed by offset printing, the viscosity of the organic conductive composition may range from 10,000 to 100,000 mPas.

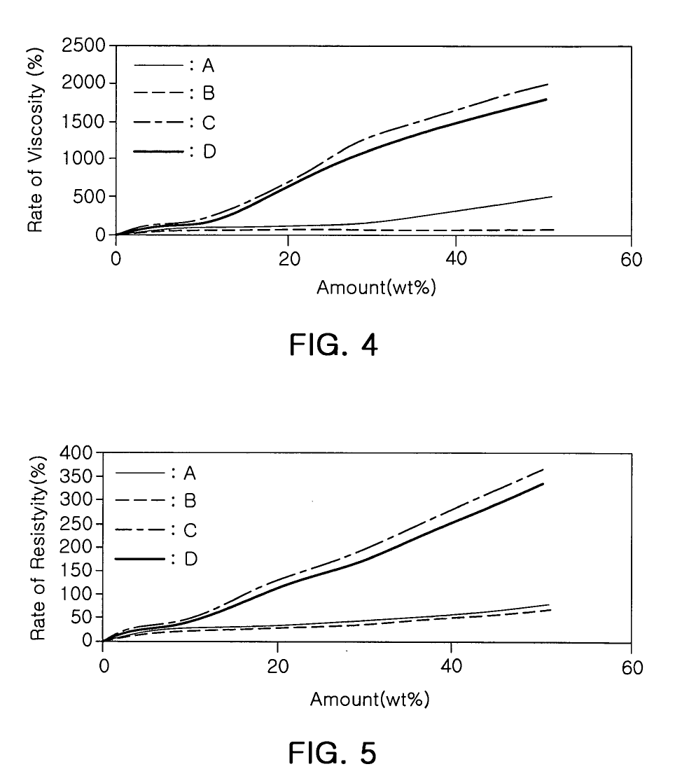

FIG. 4 is a graph showing a rate of viscosity of the organic conductive composition according to the embodiment of the present invention.

More specifically, the organic conductive composition includes the low-molecular-weight binder A or the high-molecular-weight binder B, the crosslink type amine-based viscosity control agent C or the linear type amine-based viscosity control agent D, and the rate of viscosity of such organic conductive composition according to the content of the binder and the viscosity control agent is shown in FIG. 4.

Referring to FIG. 4, it can be seen that the viscosity of the low-molecular-weight binder A and the high-molecular-weight binder B does not rapidly change according to the content, and the viscosity of the crosslink type amine-based viscosity control agent C and the linear type amine-based viscosity control agent D rapidly changes according to the content.

Therefore, the organic conductive composition having a viscosity suitable for the printing method can be prepared by adjusting the contents and mixing amounts of the low-molecular-weight binder, the high-molecular-weight binder, the crosslink type amine-based viscosity control agent, and the linear type amine-based viscosity control agent.

FIG. 5 is a graph showing a rate of resistivity of the organic conductive composition according to the embodiment of the present invention.

More specifically, the organic conductive composition includes the low-molecular-weight binder A or the high-molecular-weight binder B, the crosslink type amine-based viscosity control agent C or the linear type amine-based viscosity control agent D, and the rate of resistivity of such organic conductive composition according to the content of the binder and the viscosity control agent is shown in FIG. 5.

Referring to FIG. 5, it can be seen that the resistivity of the low-molecular-weight binder A and the high-molecular-weight binder B does not rapidly change according to the content, and the resistivity of the crosslink type amine-based viscosity control agent C and the linear type amine-based viscosity control agent D rapidly changes according to the content.

Therefore, the organic conductive composition having a viscosity suitable for the printing method can be prepared by adjusting the contents and mixing amounts of the low-molecular-weight binder, the high-molecular-weight binder, the crosslink type amine-based viscosity control agent, and the linear type amine-based viscosity control agent.

The viscosity and resistivity of the low-molecular-weight binder A and the high-molecular-weight binder B do not rapidly change according to the content, and the viscosity and resistivity of the crosslink type amine-based viscosity control agent and the linear type amine-based viscosity control agent rapidly change according to the content. Considering these features, an additive amount can be appropriately controlled.

A solvent included in the organic conductive composition according to the embodiment of the present invention is not specifically limited. Poly-alcohol, dimethyl sulfoxide (DMSO), N,N-dimethylformamide, ethylene glycol (EG), meso-erythritol, aniline, acetone, methyl ethyl ketone, isopropyl alcohol, butyl alcohol, ethyl alcohol, methyl alcohol, dimethylacetamide, hexane, toluene, chloroform, cyclohexanone, distilled water, pyridine, methylnaphthalene, octadecylamine, tetrahydrofuran, dichlorobenzene, dimethylbenzene, trimethylbenzene, nitromethane, acrylonitrile and so on may be taken as examples of the solvent. They may be used independently, or two or more of them may be combined to be used.

The content of the solvent may range from 2 to 95 parts by weight with respect to the entire composition. The viscosity of the organic conductive composition may be properly controlled depending on the content of the solvent.

An organic conductive film formed of the organic conductive composition according to the embodiment of the present invention may exhibit a surface resistance of 2000/sq. or less.

As a result of an experiment, the surface resistance (ASTM D257) of the organic conductive film at a transparency of 83% or more had an average of 700 Ω/sq or less (as a result of five measurements).

Further, the elongation of the organic conductive film was measured to be 20 to 300%. The elongation of a polyethylene terephthalate (PET) film used in a touch panel input device ranges from 30 to 300% which is similar to that of the conductive film containing the organic conductive composition according to the embodiment of the present invention.

Since a conductive film formed of an inorganic material has a large difference in elongation from a substrate, a crack is highly likely to occur during an operation. However, since the conductive film containing the organic conductive composition according to the embodiment of the present invention has similar elongation to that of a substrate, a crack is not likely to occur. Therefore, the durability of the conductive film is expected to be excellent. Further, the conductive film containing the organic conductive composition according to the embodiment of the present invention has a thermal expansion coefficient of 30 to 60 ppm/° C. which is similar to that of a substrate (in a case of PET, 18-60 ppm/° C.). Therefore, the conductive film is not likely to be peeled off.

The present invention relates to a touch panel input device including a substrate and an organic conductive film formed on the substrate and containing an organic conductive composition including a conductive polymer, a dopant, a binder, and a viscosity control agent.

The organic conductive film containing the above-described organic conductive composition may be applied to a touch panel input device requiring transparency and low surface resistance.

The substrate is not specifically limited as long as it is formed of a material upon which a conductive film is easy to form. Resin, glass and so on may be used as the substrate.

The substrate may be formed of a colored or colorless material depending on the intended use. When the substrate is provided as a display surface, a transparent material may be used. For example, PET, polycarbonate (PC), polymethyl methacrylate (PMMA), polyethylenenaphthalate (PEN), polyethersulfone (PES), cyclo-olefin copolymer (COC) and so on may be used.

In this specification, the transparency includes colorless transparency, colored transparency, translucency, colored translucency and so on.

The conductive film is formed of the organic conductive composition including a conductive polymer, a dopant, a binder, and a viscosity control agent. The specific components and contents of the organic conductive composition are as described above.

As described above, the organic conductive composition has excellent transparency, low surface resistance, and similar elongation and thermal expansion coefficient to that of the substrate. Accordingly, the conductive film is prevented from being peeled off from the substrate, which makes it possible to improve the durability of the touch panel input device.

Hereinafter, exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like reference numerals in the drawings denote like elements, and thus their description will be omitted.

FIG. 2 is a schematic cross-sectional view of a touch panel input device according to an embodiment of the present invention.

Referring to FIG. 2, the touch panel type input device according to the embodiment of the present invention includes a first substrate 11 and a first organic conductive film 12 which is formed on the first substrate 11 and composed of the above-described organic conductive composition including a conductive polymer, a dopant, a binder, an a viscosity control agent.

Further, the input device includes a second substrate 13 disposed opposite to the first substrate 11 and a second organic conductive film 14 formed on the second substrate 13. Further, the input device includes electrodes 15 and 16 formed on the first and second organic conductive films 12 and 14, respectively, and a double adhesive tape (DAT) 17 formed between the electrodes 15 and 16.

The input device according to the embodiment of the present invention is a resistive overlay touch-panel-type input device, in which the first organic conductive film 12 is deformed by a touch to come into partial contact with the second organic conductive film 14. In regions excluding the contact region, dot spacers 18 may be formed in order to provide electrical insulation.

The second substrate 13 may be formed of the same material as the first substrate 11. Further, the second organic conductive film 14 may contain the above-described organic conductive composition.

Table 1 shows reflectances and light extraction efficiencies of the touch panel input device (using a PET substrate) according to this embodiment of the present invention and a touch panel input device including an indium tin oxide (ITO) film according to the related art.

TABLE 1

| | | Refractive | Refractive | Relative | | | Light |
|---|---|---|---|---|---|---|---|
| | | index of | index of | refractive | Critical | | extraction |
| | | medium n₁ | medium n₂ | index n = n₂/n₁ | angle θ_{c} | Reflectance | efficiency[%] |
| Input device | PET-ITO | 1.66 | 1.95 | 1.17 | | 0.0065 | |
| according | ITO-package | 1.95 | 1.00 | 0.51 | 31 | 0.1037 | 7 |
| to related | air | | | | | | |
| art | Package | 1.00 | 1.95 | 1.95 | | 0.1037 | |
| | air-ITO | | | | | | |
| | ITO-PET | 1.95 | 1.66 | 0.85 | 58 | 0.0065 | 18 |
| | PET-outside | 1.66 | 1.00 | 0.60 | 37 | 0.0616 | 9 |
| Input device | PET-organic | 1.66 | 1.47 | 0.89 | 62 | 0.0037 | 20 |
| according | conducive film | | | | | | |
| to present | Organic | 1.47 | 1.00 | 0.68 | 43 | 0.0362 | 12 |
| invention | conducive | | | | | | |
| | film-package | | | | | | |
| | air | | | | | | |
| | Package | 1.00 | 1.47 | 1.47 | | 0.0362 | |
| | air-organic | | | | | | |
| | conducive film | | | | | | |
| | Organic | 1.47 | 1.66 | 1.13 | | 0.0037 | |
| | conducive | | | | | | |
| | film-PET | | | | | | |
| | PET-outside | 1.66 | 1.00 | 0.60 | 37 | 0.0616 | 9 |

Referring to Table 1, since the conductive film according to the embodiment of the present invention has a small difference in refractive index from PET; the critical angle therebetween is large. Accordingly, it can be seen that the light extraction efficiency is excellent.

FIG. 3 is a schematic cross-sectional view of a touch panel input device according to another embodiment of the present invention.

Referring to FIG. 3, the touch panel input device according to the embodiment of the present invention includes a first substrate 21 and a first organic conductive film 22 which is formed on the first substrate 21 and composed of the above-described organic conductive composition including a polymer, a dopant, and a binder.

Further, the input device includes a second substrate 23 disposed opposite to the first substrate 21 and a second organic conductive film 27 which is formed on the second substrate 23. First and second electrodes 24 and 25 may be formed on the first and second organic conductive films 22 and 27, respectively.

The first organic conductive film 22 and the second organic conductive film 27 may be bonded to the first substrate 21 and the second substrate 23 through an optical clear adhesive (OCA) 26. The touch-panel-type input device according to this embodiment of the present invention is a capacitive touch-panel-type input device which operates as the first and second organic conductive films 22 and 27 detect a change in electrostatic capacity caused by a touch of the first substrate 21.

The first organic conductive film 22 or the second organic conductive film 27 may be patterned in a stripe or diamond shape unlike the resistive overlay type.

Table 2 shows reflectances and light extraction efficiencies of the touch panel input device (using a PET substrate) according to this embodiment of the present invention and a touch panel input device including an ITO film according to the related art.

TABLE 2

| | | Refractive | Refractive | Relative | | | Light |
|---|---|---|---|---|---|---|---|
| | | index of | index of | refractive | Critical | | extraction |
| | | medium n₁ | medium n₂ | index n = n₂/n₁ | angle θ_{c} | Reflectance | efficiency[%] |
| Input device | PET-ITO | 1.66 | 1.95 | 1.17 | | 0.0065 | |
| according | ITO-OCA | 1.95 | 1.47 | 0.75 | 49 | 0.0197 | 14 |
| to related | OCA-PET | 1.47 | 1.66 | 1.13 | | 0.0037 | 32 |
| art | PET-outside | 1.66 | 1.00 | 0.60 | 37 | 0.0616 | 9 |
| Input device | PET-organic | 1.66 | 1.47 | 0.89 | 62 | 0.0037 | 20 |
| according | conducive film | | | | | | |
| to present | Organic | 1.47 | 1.47 | 1.00 | 90 | 0.0000 | |
| invention | conducive | | | | | | |
| | film-OCA | | | | | | |
| | OCA-PET | 1.47 | 1.66 | 1.13 | | 0.037 | 32 |
| | PET-outside | 1.66 | 1.00 | 0.60 | 37 | 0.0616 | 9 |

Referring to Table 2, since the conductive film according to the embodiment of the present invention has a small difference in refractive index from PET; the critical angle therebetween is large. Accordingly, it can be seen that the light extraction efficiency is excellent.

Hereinafter, a method of manufacturing the touch-panel-type input device according to the embodiment of the present invention will be described.

First, an organic conductive composition including a conductive polymer, a dopant, a binder, and a viscosity control agent is prepared. The specific components and contents of the organic conductive composition have been already described above.

The organic conductive composition is used to form an organic conductive film on a substrate. The process of forming the conductive film using the organic conductive composition is not specifically limited. For example, inkjet printing, screen printing, gravure printing, or offset printing may be used.

More specifically, the viscosity of the organic conductive composition may be properly controlled depending on the applied printing method.

When the conductive film is formed by the inkjet printing, the viscosity of the organic conductive composition may range from 1 to 50 mPas. When the conductive film is formed by the screen printing, the viscosity of the organic conductive composition may range from 300 to 70,000 mPas.

The inkjet printing or screen printing is suitable for patterning and forming a conductive film.

When the conductive film is formed by the gravure printing, the viscosity of the organic conductive composition may range from 10 to 300 mPas. When the conductive film is formed by the offset printing, the viscosity of the organic conductive composition may range from 10,000 to 100,000 mPas. The gravure printing may be applied to pattern printing as well as the entire printing.

As the viscosity of the organic conductive composition is controlled in the above-described manner, the conductive film may be formed by the printing method. A conductive film using ITO according to the related art is formed by deposition, exposure, development and so on. Therefore, material consumption is high, and the formation process is complicated.

However, when the organic conductive composition according to the embodiment of the present invention is used, the conductive film may be formed by the printing and heat treatment process. Further, material consumption is low, and the formation process is simple.

Before the conductive film is formed, a surface treatment may be performed on a surface of the substrate where the conductive film is to be formed. The surface treatment may improve an adhesive force between the conductive film and the substrate. When the conductive film is formed of a composition including a conductive polymer according to the related art, an adhesive force between the conductive film and the substrate is so low that its product quality decreases.

In this embodiment of the present invention, the surface treatment performed on the substrate increases the surface tension of the substrate to thereby improve the adhesive force between the organic conductive composition and the substrate.

The surface treatment is not specifically limited. For example, infrared ray (IR) irradiation, plasma treatment, ion shower, UV irradiation, or corona treatment may be applied.

More specifically, since a PET film has a small surface tension of 30-45 dyne/cm, it is easily peeled off from the organic conductive film. However, the surface thereof may be polarized by the surface treatment such that the surface tension increases to 45-80 dyne/cm. Accordingly, the adhesive force between the PET film and the organic conductive film may increase to improve durability.

To manufacture the resistive overlay touch-panel-type input device shown in FIG. 2, a second organic conductive film is formed on the second substrate, and a second substrate is formed so as to be disposed opposite to the first substrate. At this time, electrodes may be formed on the first and second organic conductive films, respectively, and an insulating spacer may be inserted between the electrodes.

To manufacture the capacitive touch-panel-type input device shown in FIG. 3, a second substrate is formed so as to be disposed opposite to the first substrate, and electrodes may be formed between the first and second organic conductive films.

According to the embodiments of the present invention, the organic conductive composition has excellent transparency and low surface resistance. Accordingly, the organic conductive composition may be properly used in the touch panel input device. Further, the organic conductive composition is composed of a similar material to the substrate of the input device and has a small difference in thermal expansion coefficient from the substrate. Therefore, the organic conductive composition may increase the durability of the input device.

The organic conductive composition according to the embodiment of the present invention has a viscosity ranging from 1 to 100,000 mPas and its viscosity can be easily controlled according to a printing method.

While the present invention has been shown and described in connection with the exemplary embodiments, it will be apparent to those skilled in the art that modifications and variations can be made without departing from the spirit and scope of the invention as defined by the appended claims.

What is claimed is:

1. An organic conductive composition comprising:
10 to 70 parts by weight of a conductive polymer;
0.01 to 40 parts by weight of a dopant selected from the group consisting of Lewis acids capable of accepting electrons;
1 to 40 parts by weight of a binder; and
1 to 30 parts by weight of a viscosity control agent,
wherein the organic conductive composition has a viscosity ranging from 1 to 100,000 mPas.

2. The organic conductive composition of claim 1, wherein the viscosity control agent comprises one or more material selected from the group consisting of diaminodiphenylmethane (DMA), 4,4′-oxydianiline (ODA), diethylene triamine (DETA), triethylene tetramine (TETA), ethylene diamine (EDA), and hexamethylenediamine (HMDA).

3. The organic conductive composition of claim 1, wherein the organic conductive composition has a viscosity ranging from 60 to 200 mPas and is applied to gravure printing.

4. The organic conductive composition of claim 1, wherein the organic conductive composition has a viscosity ranging from 300 to 70,000 mPas and is applied to screen printing.

5. The organic conductive composition of claim 1, wherein the organic conductive composition has a viscosity ranging from 1 to 50 mPas and is applied to inkjet printing.

6. The organic conductive composition of claim 1, wherein the organic conductive composition has a viscosity ranging from 10,000 to 100,000 mPas and is applied to offset printing.

7. The organic conductive composition of claim 1, wherein the conductive polymer comprises one or more material selected from the group consisting of polythiopene, polyaniline, polyacetylene, polypyrrole, polyphenylenevinylene.

8. The organic conductive composition of claim 1, wherein the dopant comprises one or more material selected from the group consisting of sulfonate compound, a boron compound, and a phosphate compound.

9. A touch panel input device, comprising:
a first substrate; and
a first organic conductive composition comprising: 10 to 70 parts by weight of a conductive polymer; 0.01 to 40 parts by weight of a dopant selected from the group consisting of Lewis acids capable of accepting electrons; 1 to 40 parts by weight of a binder; and 1 to 30 parts by weight of a viscosity control agent, wherein the organic conductive composition has a viscosity ranging from 1 to 100,000 mPas.

10. The touch panel input device of claim 9, wherein the first substrate is formed of polyethylene terephthalate (PET), polycarbonate (PC), polymethyl methacrylate (PMMA), polyethylenenaphthalate (PEN), polyethersulfone (PES), or cyclo-olefin copolymer (COC).

11. The touch panel input device of claim 9, further comprising:
a second substrate disposed opposite to the first substrate; and
a second organic conductive film formed on the second substrate,
wherein the first organic conductive film is deformed by a touch to partially come in contact with the second organic conductive film.

12. The touch panel input device of claim 9, further comprising:
a second substrate disposed opposite to the first substrate; and
a second organic conductive film formed on the second substrate,
wherein the first and second organic conductive films detect a change in electrostatic capacity caused by a touch of the first substrate.

13. A method of manufacturing a touch panel input device, the method comprising:
preparing an organic conductive composition, the organic conductive composition comprising:
10 to 70 parts by weight of a conductive polymer;
0.01 to 40 parts by weight of a dopant selected from the group consisting of Lewis acids capable of accepting electrons;
1 to 40 parts by weight of a binder; and
1 to 30 parts by weight of a viscosity control agent,
wherein the organic conductive composition has a viscosity ranging from 1 to 100,000 mPas; and
forming a first organic conductive film on the first substrate using the organic conductive composition.

14. The method of claim 13, wherein the first organic conductive film is formed by inkjet printing, screen printing, gravure printing, or offset printing.

15. The method of claim 13, further comprising performing a surface treatment on a surface of the first substrate where the first organic conductive film is to be formed, in order to increase the surface tension of the first substrate, before forming the first organic conductive film on the first substrate.
